(19) United States
(12) Patent Application Publication
(10) Pub. No.: US 2019/0386229 A1
(43) Pub. Date: Dec. 19, 2019

(54) FLEXIBLE OLED COMPONENT AND METHOD FOR MANUFACTURING THE SAME

(71) Applicant: Shenzhen China Star Optoelectronics Technology Co., Ltd., Shenzhen, Guangdong (CN)

(72) Inventor: Wenjie LI, Shenzhen, Guangdong (CN)

(73) Assignee: Shenzhen China Star Optoelectronics Technology Co. , Ltd., Shenzhen, Guangdong (CN)

(21) Appl. No.: 15/554,450

(22) PCT Filed: Jun. 27, 2017
(86) PCT No.: PCT/CN2017/090366

§ 371 Date: Aug. 30, 2017

(30) Foreign Application Priority Data
Jun. 7, 2017 (CN) 201710422087.5

(51) Int. Cl. H01L 51/00; H01L 51/52; H01L 51/56

(52) U.S. Cl. CPC H01L 51/0097; H01L 2251/5338; H01L 51/56; H01L 51/5253

(57) ABSTRACT

Disclosed is a flexible OLED component which includes a flexible substrate, an OLED component provided on the flexible substrate, and an encapsulation film encapsulating the OLED component. The flexible substrate and the flexible encapsulation film contain a shape memory material. When an external environment changes, the flexible OLED component deforms accordingly, and therefore it has good deformation characteristics.

### CROSS-REFERENCE TO RELATED APPLICATIONS

This application claims the priority of Chinese patent application CN201710422087.5, entitled “Flexible OLED component and method for manufacturing the same” and filed on Jun. 7, 2017, the entirety of which is incorporated herein by reference.

### FIELD OF THE INVENTION

The present disclosure relates to the technical field of OLED components, and in particular, to a flexible OLED component and a method for manufacturing the same.

### BACKGROUND OF THE INVENTION

OLED (Organic Light Emitting Diode) components are widely used for their advantages such as good self-luminous characteristics, high contrast, fast response, and flexible display.

Flexible OLED panels have become an important research direction of organic light-emitting components. A flexibility of a panel can be achieved by using a flexible substrate instead of a conventional glass substrate. Commonly used flexible substrates include metal films and polymer films. In comparison with metal films, polymer films have a better flexibility and a lighter texture.

A shape memory material refers to a material which can adjust its shape, strain, and rigidity in response to a stimulus of an external physical environment or chemical environment (such as temperature, electromagnetic field, solvent, light, pH), and can return from a deformed state to its original when the external environment changes again in a particular way or with regularity. The shape memory materials are a new type of intelligent material, and are widely used in many fields such as aerospace, electronics, industry, and medicine.

Shape memory polymers (SMPs) (The heat-sensitive shape memory polymer is taken as an example, and its shape memory effect is shown in FIG. 1) are indispensable in shape memory materials, and are widely used in textile industry. Wrinkles formed in yarns and clothes made from shape memory polymers at room temperature may disappear as the temperature rises, and the shape memory polymers have an intelligent wrinkle-proof function.

The present disclosure provides a method for using a shape memory polymer as a flexible OLED substrate and an encapsulation film, and has a bright application prospect in the field of intelligent wearable display.

### SUMMARY OF THE INVENTION

In view of the problems in the prior art, an object of the present disclosure is to provide a flexible OLED component. The flexible OLED component has a flexible substrate and a flexible encapsulation film, both of which contain a shape memory material. When an external environment changes, the flexible OLED component deforms accordingly, and has good deformation characteristics. The present disclosure further provides a method for manufacturing the flexible OLED component. The method has advantages of simple operation, easy availability of raw materials, and easy large-scale industrial production.

According to one aspect of the present disclosure, a flexible OLED component is provided. The flexible OLED component comprises a flexible substrate, an OLED component provided on the flexible substrate, and an encapsulation film encapsulating the OLED component. The flexible substrate and the encapsulation film contain a shape memory material.

According to some embodiments of the present disclosure, the shape memory material includes, but is not limited to, a heat-sensitive shape memory material, an electro-sensitive shape memory material, and a magnetically sensitive shape memory material.

According to preferred embodiments of the present disclosure, the heat-sensitive shape memory material includes, but is not limited to, substituted or unsubstituted polyamide, polyolefin, polyurethane, polyester and polynorbornene.

In some specific embodiments, the heat-sensitive shape memory material includes at least one of polyimide, polyetherimide, styrene/butadiene copolymer, polyisoprens, crosslinked polyethylene, crosslinked polyvinyl alcohol, poly norbornene, and fluorinated olefin.

According to some embodiments of the present disclosure, an amount of the shape memory material in the flexible substrate is in a range from 50 wt % to 80 wt %.

According to preferred embodiments of the present disclosure, an amount of the shape memory material in the encapsulation film is in a range from wt % 50 to 80 wt %.

According to some embodiments of the present disclosure, the encapsulation film has a film structure containing a shape memory material.

In some embodiments of the present disclosure, the flexible substrate is the same as the package film, and both are thin films containing a shape memory material.

In some embodiments of the present disclosure, the flexible substrate contains conductive particles. The conductive particles include, but are not limited to, metals, metal oxides, metal nitrides and carbon materials, preferably one or more of silver, copper, gold, aluminum and alloys thereof, alumina, magnesium oxide, zinc oxide, aluminum nitride, and boron nitride.

Since the conductive particles are added, the flexible substrate has a conductive function, and may serve as either a substrate or an anode of the OLED component.

In some embodiments of the present disclosure, the flexible substrate comprises a two-layer film structure. A bottom layer is a film containing no conductive particles, and a layer close to the OLED component is a film containing conductive particles.

According to the OLED component of the present disclosure, both the flexible substrate and the flexible encapsulation film contain a shape memory material. When an external environment changes, the flexible OLED component deforms accordingly and therefore has good deformation characteristics.

According to some embodiments of the present disclosure, as an OLED component understood by those skilled in the art, the OLED component generally includes an anode, a hole transport layer, a light emitting layer, an electron transport layer, and a cathode arranged from bottom to top. When the flexible substrate contains conductive particles, it can be used as the anode of the OLED component.

According to the other aspect of the present disclosure, a method for manufacturing the OLED component is provided. The method comprises the following steps:

step A, a flexible substrate and an encapsulation film is manufactured, both of which contain a shape memory material;

step B, an OLED component is manufactured on the flexible substrate; and

step C, the OLED component is encapsulated with the encapsulation film to obtain the flexible OLED component.

According to some embodiments of the present disclosure, the flexible substrate is manufactured by the following method:

the shape memory material is heated into a molten state, an initiator and a crosslinking agent is added therein, a substrate solution is obtained after stirring and dissolution; and

the substrate solution is subjected to film formation treatment to obtain a flexible substrate

According to some embodiments of the present disclosure, the flexible substrate is manufactured by the following method:

the shape memory material is heated into a molten state, an initiator and a crosslinking agent is added therein, and a substrate solution is obtained after stirring and dissolution;

conductive particles are added into the substrate solution, and after stirring and dissolution, a substrate solution to which the conductive particles are added is obtained; and

the substrate solution to which the conductive particles are added is subjected to film formation treatment to obtain a flexible substrate containing conductive particles.

In some embodiments, the amount of the conductive particles is in a range from 0.5 wt % to 10.0 wt %.

According to some embodiments of the present disclosure, the flexible substrate is manufactured by the following method:

the shape memory material is heated into a molten state, an initiator and a crosslinking agent is added therein, and a substrate solution is obtained after stirring and dissolution;

conductive particles are added into the substrate solution, and after stirring and dissolution, a substrate solution to which the conductive particles are added is obtained;

the substrate solution is subjected to film formation treatment to obtain a flexible substrate base layer;

the substrate solution to which the conductive particles are added is subjected to film formation treatment to manufacture a conductive layer on the flexible substrate base layer, so as to obtain a flexible substrate having a two-layer film structure.

According to some preferred embodiments of the present disclosure, the encapsulation film is manufactured by the following method:

the shape memory material is heated into a molten state, an initiator and a crosslinking agent is added therein, and a film solution is obtained after stirring and dissolution; and

the film solution is subjected to film formation treatment to obtain an encapsulation film.

According to some preferred embodiments of the present disclosure, the shape memory material includes, but is not limited to, a heat-sensitive shape memory material, an electro-sensitive shape memory material, and a magnetically sensitive shape memory material.

According to preferred embodiments of the present disclosure, the heat-sensitive shape memory material includes, but is not limited to, substituted or unsubstituted polyamide, substituted or unsubstituted polyolefin, substituted or unsubstituted polyurethane, substituted or unsubstituted polyester, and polynorbornene.

In some specific embodiments, the heat-sensitive shape memory material includes at least one of polyimide, polyetherimide, styrene/butadienecopolymer, polyisoprene, crosslinked polyethylene, crosslinked polyvinyl alcohol, poly norbomene, and fluorinated olefin.

According to one embodiment of the present disclosure, there is no particular limitation on the initiator, and a conventional initiator in the art can be used, preferably including at least one of benzoyl peroxide, t-butyl peroxy benzoate, ammonium persulfate, and potassium persulfate.

According to one preferred embodiment of the present disclosure, there is no particular limitation on the crosslinking agent, and conventional organics having a double bond in the art can be used, preferably including at least one of acrylic acid, N, N-methylenebisacrylamide, and methylmethacrylate.

In preferred embodiments of the present disclosure, a weight ratio among the shape memory material, the initiator, and the crosslinking agent is 50 to 80: 0.5 to 5: 0 to 15, preferably 55 to 75: 1 to 3: 0 to 10.

According to some embodiments of the present disclosure, there is no particular limitation on film formation, and a film formation method known to those skilled in the art can be used. For example, the substrate solution or the film solution is spin-coated on a substrate and then a process of demolding and drying is performed.

According to preferred embodiments of the present disclosure, the flexible OLED component is manufactured by encapsulating the OLED component with the encapsulation film by means of an encapsulation adhesive.

The present disclosure has the following advantages and beneficial effects.

1. Each of the flexible OLED component, the flexible substrate, and the encapsulation film of the present disclosure contains a shape memory material, and when an external environment changes, they deform accordingly. Therefore, they have good deformation characteristics.

2. Combined with the display technology, the flexible OLED component of the present disclosure can realize intelligent display.

3. The shape memory material of the flexible OLED component of the present disclosure can also be replaced with other shape memory materials, such as a photosensitive shape memory material and a chemically sensitive shape memory material, which are sensitive to an external stimulus. Thus, application of flexible OLED components is extended.

4. The flexible OLED component of the disclosure has the advantages that the manufacturing method thereof is simple and raw materials are easily obtained, andis suitable for mass production.

### BRIEF DESCRIPTION OF THE DRAWINGS

The accompanying drawings provide further understandings of the present disclosure and constitute one part of the description. The drawings are used for interpreting the present disclosure together with the embodiments, not for limiting the present disclosure. In the drawings:

FIG. 1 schematically shows a shape memory effect of a heat-sensitive shape memory polymer;

FIG. 2 schematically shows a structure of a flexible OLED component according to Embodiment 1 of the present disclosure;

FIG. 3 schematically shows a structure of a flexible OLED component according to Embodiment 2 of the present disclosure; and

FIG. 4 schematically shows a structure of a flexible OLED component according to Embodiment 3 of the present disclosure.

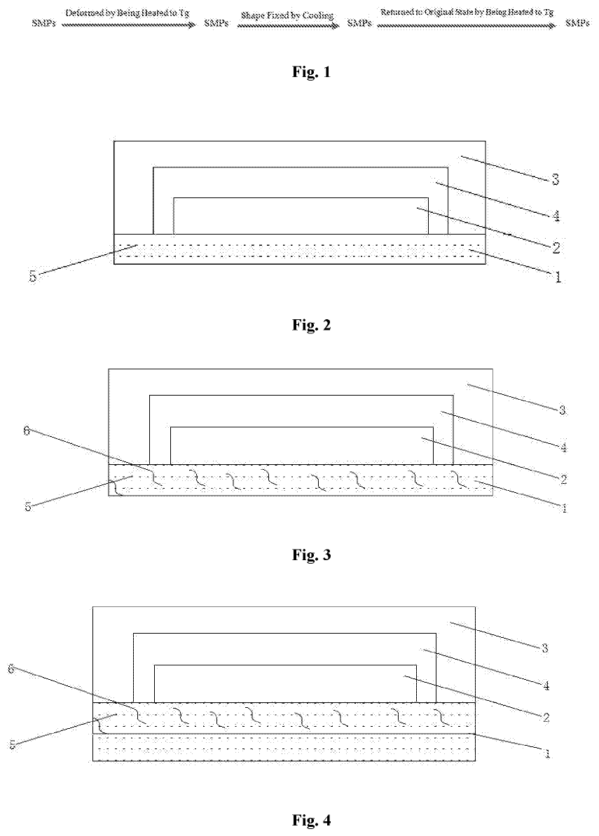

### DETAILED DESCRIPTION OF THE EMBODIMENTS

The technical solutions of the present disclosure will be further described blow with reference to embodiments.

As shown in FIGS. 2 and 3, a flexible OLED component comprises a flexible substrate 1, an OLED component 2 provided on the flexible substrate 1, and an encapsulation film 3 encapsulating the OLED component 2. The OLED component 2 and the encapsulation film 3 are connected to each other by means of an encapsulation adhesive 4.

In one embodiment of the present disclosure, the flexible substrate 1 and the encapsulation film 3 of the flexible OLED component of the present disclosure have a same constituent and a same structure, and are films containing a shape memory material (as shown in FIG. 2).

In one embodiment of the present disclosure, the flexible substrate 1 of the flexible OLED component of the present disclosure contains conductive particles 6, and is an anode of the OLED component at the same time (as shown in FIG. 3).

In one embodiment of the present disclosure, the flexible substrate 1 of the flexible OLED component of the present disclosure has a two-layer structure. A bottom layer is a film having the same constituent and structure as the encapsulation fi1m3.An upper layer is a film containing conductive particles 6, and is an anode of the OLED component at the same time (as shown in FIG. 4).

### Embodiment 1

A method for manufacturing an OLED component as shown in FIG. 2 comprises following steps.

(1) Polyvinyl alcohol powder is heated to 80° C. and is caused to melt, followed by an addition of acrylic acid, N,N-methylenebisacrylamide, and potassium persulfate. The mixtures then stirred until the added substances melt so as to obtain a substrate solution and a film solution.

(2) The substrate solution and the film solution are coated onto a substrate separately and dried so as to obtain a flexible substrate and an encapsulation film.

(3) The flexible substrate is fixed on a stage; and then an anode, a hole transport layer, a light emitting layer, an electron transport layer, and a cathode are prepared in sequence on the flexible substrate.

(4) The OLED component is capsulated by the encapsulation film by means of an encapsulation adhesive, thus obtaining a flexible OLED component.

### Embodiment 2

A method for manufacturing an encapsulating structure as shown in FIG. 3 comprises following steps.

(1) Polynorbornene powder is heated to 50° C. and is caused to melt, followed by an addition of methyl methacrylate and benzoyl peroxide. The mixture is then stirred until the added substances melt, so as to obtain a film solution.

(2) The film solution is coated onto a substrate and is dried to obtain an encapsulation film.

(3) Carbon nanotubes are added and dissolved into the film solution obtained instep (1) to obtain a substrate solution.

(4) The substrate solution is coated onto the substrate, and is dried to obtain a flexible substrate.

(5) The flexible substrate is fixed on a stage; and then an anode, a hole transport layer, a light emitting layer, an electron transport layer, and a cathode are prepared in sequence on the flexible substrate.

(6) The OLED component is capsulated by the encapsulation film by means of an encapsulation adhesive, thus obtaining a flexible OLED component.

### Embodiment 3

A method for manufacturing an encapsulating structure as shown in FIG. 4 comprises following steps.

(1) Polyisoprene powder is heated to 65° C. and is caused to melt, followed by an addition of acrylic acid, methyl methacrylate, and t-butyl peroxy benzoate. The mixture is then stirred until the added substances melt so as to obtain a first solution.

(2) The first solution is coated onto a substrate and is dried to obtain a flexible substrate base layer and an encapsulation film.

(3) Carbon nanotubes are added and dissolved into the first solution obtained instep (1) so as to obtain a second solution.

(4) The second solution is coated onto the flexible substrate base layer obtained in step (2), and is dried to obtain a flexible substrate.

(5) The flexible substrate is fixed on a stage; and then an anode, a hole transport layer, a light emitting layer, an electron transport layer, and a cathode are prepared in sequence on the flexible substrate.

(6) The OLED component is capsulated by the encapsulation film by means of an encapsulation adhesive, thus obtaining a flexible OLED component.

Any value mentioned in the present disclosure includes all the values of a unit being added each time from a minimum value to a maximum value if there is only an interval of two units between any minimum value and any maximum value. For example, if it is stated the amount of a component, or a value of process variables such as temperature, pressure, and time is from 50 to 90, this means in the description that it recites values of from 51 to 89, 52 to 88 . . . 69 to 71, and 70 to 71. For non-integer values, it may be appropriate to consider 0.1, 0.01, 0.001 or 0.0001 as a unit. These are only a few specific examples. In this application, all possible combinations of numerical values between the minimum value and the maximum value recited in a similar manner are considered to have been disclosed.

It should be noted that the above embodiments are only used for illustrating, rather than restricting the present disclosure. The present disclosure is illustrated in detail in combination with embodiments hereinabove, but it can be understood that, the words used are explanatory ones, rather than restrictive ones. Changes can be made to the present disclosure according to the protection scopes of the claims of the present disclosure, and amendments can be made to the present disclosure as long as they do not go beyond the spirit and scope of the present disclosure. While the present disclosure described herein relates to specific methods, materials, and embodiments, it does not mean that the present disclosure is limited to the particular embodiments disclosed therein. Instead, the present disclosure may be extended to all other methods and applications having a same function.

### LIST OF REFERENCE NUMBERS

1—Flexible substrate;

2—OLED component;

3—Encapsulation film;

4—Shape memory material;

5—Conductive particles; and

6—Encapsulation adhesive.

1. A flexible OLED component, comprising
a flexible substrate;
an OLED component provided on the flexible substrate; and
an encapsulation film encapsulating the OLED component;
wherein the flexible substrate and the encapsulation film contain a shape memory material.

2. The flexible OLED component according to claim 1, wherein the shape memory material includes, but is not limited to, a heat-sensitive shape memory material, an electro-sensitive shape memory material, and a magnetically sensitive shape memory material.

3. The flexible OLED component according to claim 2, wherein the heat-sensitive shape memory material includes, but is not limited to, substituted or unsubstituted polyamide, polyolefin, polyurethane, polyester and polynorbomene.

4. The flexible OLED component according to claim 3, wherein the heat-sensitive shape memory material includes at least one of polyimide, polyetherimide, styrene/butadiene copolymer, polyisoprene, crosslinked polyethylene, crosslinked polyvinyl alcohols, poly norbornene, and fluorinated olefin.

5. The flexible OLED component according to claim 1, wherein an amount of the shape memory material in the flexible substrate is in a range from 50 wt % to 80 wt %.

6. The flexible OLED component according to claim 1, wherein an amount of the shape memory material in the encapsulation film is in a range from 50 wt % to 80 wt %.

7. A method for manufacturing a flexible OLED component, comprising the following steps:
step A, manufacturing a flexible substrate and an encapsulation film containing a shape memory material;
step B, manufacturing an OLED component on the flexible substrate; and
step C, encapsulating the OLED component with the encapsulation film to obtain the flexible OLED component.

8. The method according to claim 7, wherein the flexible OLED component comprises:
a flexible substrate;
an OLED component provided on the flexible substrate; and
an encapsulation film encapsulating the OLED component;
wherein the flexible substrate and the encapsulation film contain a shape memory material.

9. The method according to claim 7, wherein the shape memory material includes, but is not limited to, a heat-sensitive shape memory material, an electro-sensitive shape memory material, and a magnetically sensitive shape memory material.

10. The method according to claim 9, wherein the heat-sensitive shape memory material includes, but is not limited to, substituted or unsubstituted polyamide, polyolefin, polyurethane, polyesters and polynorbornene.

11. The method according to claim 10, wherein the heat-sensitive shape memory material includes at least one of polyimide, polyetherimide, styrene/butadiene copolymer, polyisoprene, crosslinked polyethylene, crosslinked polyvinyl alcohol, poly norbornene, and fluorinated olefin.

12. The method according to claim 7, wherein an amount of the shape memory material in the flexible substrate is in a range from 50 wt % to 80 wt %.

13. The method according to claim 7, wherein an amount of the shape memory material in the encapsulation film is in a range from 50 wt % to 80 wt %.
